(19) United States
(12) Patent Application Publication
(10) Pub. No.: US 2003/0141907 A1
(43) Pub. Date: Jul. 31, 2003

(54) Current-sharing modular supply method and circuit

(76) Inventors: Antonio Canova, Montevarchi (IT); Minho Kim, Anghiari (IT)

Correspondence Address: Waddey & Patterson, P.C., AmSouth Center, Suite 302, 200 Clinton Avenue, Huntsville, AL, 35801, US

(21) Appl. No.: 10/319,446

(22) Filed: Dec. 13, 2002

(30) Foreign Application Priority Data
Dec. 13, 2001 (EP) 01830762.9

(51) Int. Cl. H03K 4/06

(52) U.S. Cl. 327/131; 307/52

(57) ABSTRACT

The circuit comprises a plurality of supply modules for delivering current to a common load. Each supply module is equipped with a driving circuit for controlling the current delivered by the module. The supply modules are connected together by a share bus on which a signal is present for balancing the current delivered by each supply module, in such as way as to control and reduce the difference between the current delivered by a dominant supply module and the current delivered by the remaining supply modules of the circuit. Associated to each supply module are means for generating a PWM signal, the duration of which is proportional to the current delivered by the respective supply module. In addition, each supply module is connected to the share bus in such a way that on the latter there is present a digital share signal, which is a function of the digital PWM signal generated by the dominant supply module. In each supply module, means are provided for generating an error signal, the said means generating, on the basis of the PWM signal of the module itself and on the basis of the digital share signal, an error signal, which constitutes a feedback signal for the driving circuit of the supply module.

This application claims benefit of co-pending European Patent Application No. 01830762.9, filed on Dec. 13, 2001 and entitled “Current-sharing Modular Supply Method and Circuit,” the disclosure of which is hereby incorporated by reference.

### BACKGROUND OF THE INVENTION

The present invention relates to a power supply circuit and, more particularly, to a current-sharing power supply circuit that includes a plurality of power supplies or power-supply modules connected to the same load, each of which supplying to the load one part of the total current absorbed by the load itself. The invention specifically pertains to a circuit that enables balancing or equalizing of the currents delivered by the individual power-supply modules to the load so that the currents delivered by the modules are substantially the same or vary within acceptable limits.

The invention also relates to a method for the control of a system comprising a plurality of current-sharing power-supply modules connected to a single load.

It is known in the prior art that it is frequently advantageous to use a plurality of power-supply modules connected in parallel to supply power to the same load. Each power-supply module delivers one part of the total current absorbed by the load. Power-supply systems of this type, which are referred to as “current-sharing supply systems”, are commonly used whenever it is necessary to have available a modular system in which it is possible to increase the total current that can be delivered as the system grows in size and/or when it is necessary to have available a redundant system, i.e., one that is able to supply the load even when one or more of the power-supply modules fail.

Typical applications of current-sharing systems are found in the telecommunications sector, where the amount of current to be delivered may rise with the gradual increase in traffic (for example, with the increase in number of users connected to a fixed or mobile telephone network). The modularity of the power-supply system makes it possible to increase the power by simply adding new modules rather than replacing the power supplies.

In these applications, it is also important for the system to be redundant so that the failure of one or more power-supplies does not interrupt the supply of power to the load. Current sharing power supply systems can be designed to be redundant by oversizing the total number of modules with respect to the maximum power that can be absorbed by the load.

Current sharing power supply systems are also more economical than other power supply systems because they can be designed to supply very large loads using multiple small power-supply modules.

One of the problems associated with current-sharing power supply systems arises due to the fact that the various power supply modules need to be operated under approximately uniform operating conditions, i.e., the various power supply modules all need to deliver approximately the same current. If the system becomes unbalanced, i.e., one of the modules tends to deliver a current that is substantially higher than the current supplied by the other modules, considerable problems can be created. In the first place, the module that delivers the higher current has a lower life and hence tends to fail more rapidly. In addition, the lack of homogeneity in the conditions of current delivery between the individual power-supply modules leads to nonhomogeneous heating inside the cabinets in which the power supplies are housed. This causes problems with regard to cooling in the system.

As a result, systems have been studied for controlling the conditions of operation of the individual power-supply modules. Control systems for the purpose are described, for instance, in U.S. Pat. Nos. 5,594,286 and 4,924,170.

Normally, the individual power-supply modules of a current-sharing system are connected to a share bus in order to guarantee balancing between the various power-supply modules. The share bus includes an analog signal, which is proportional to the intensity of the current delivered by the particular power-supply module that is instantaneously delivering the maximum current. This module is defined in the art as the “dominant supply module” and this definition will be used in the present context hereinafter. The analog signal is supplied to each power-supply module and an error signal is generated for each power supply module using the analog signal on the share bus and an analog signal that is proportional to the current delivered by each individual module. The error signal for each module is proportional to the difference between the current delivered by the dominant module (known via the analog signal on the share bus) and the current delivered by the individual module associated with the error signal. Each error signal constitutes a feedback signal, which intervenes in the control loop of the driving circuit of the power-supply module associated with the error signal, to increase the output voltage, and hence the output current.

The main drawback of these control systems lies in the fact that the analog signal on the share bus is sensitive to electromagnetic noise. The greater the number of power-supply modules connected to the share bus, the greater the electromagnetic noise. In many cases, the electromagnetic noise becomes so great that the analog signal on the share bus cannot be used to balance the individual power-supply modules.

What is needed, then, is a control circuit and method for balancing currents in a current-sharing power supply that is not as sensitive to electromagnetic noise.

### SUMMARY OF THE INVENTION

One object of the present invention is to provide a circuit and control method for current sharing supply systems that overcomes the above-referenced drawbacks.

This and other objects and advantages, which will become clear to persons skilled in the art from a review of the following text, are obtained substantially by a circuit for balancing the load currents delivered by a plurality of current-supply modules to a common load. The circuit is designed to be used with power-supply modules that are equipped with driving circuits for controlling the current delivered by each module and that are connected together using a share bus. The circuit generates a signal on the share bus that is used to balance the current delivered by each supply module in such a way as to control and reduce the difference between the current delivered by a dominant supply module and the current delivered by the remaining supply modules of the circuit.

The circuit includes means, in each power supply module, for generating a digital pulse-width modulation signal (herein after also shortly indicated as digital PWM (=Pulse Width Modulation) signal), having a pulse duration, or pulse width, that is proportional to the current delivered by the power supply module associated with the means.

Each power supply module is connected to the share bus so that a digital share signal, which is a function of the digital pulse-width modulation signal generated by the dominant supply module, i.e., the power supply module supplying the greatest amount of current to the load, is present on the share bus.

In each power supply module, the digital pulse-width modulation signal of the module and the digital share signal are used to generate an error signal that is a function of the difference between the current delivered by the supply module itself and the current delivered by the dominant supply module. The error signal of a power supply module constitutes a feedback signal for the driving circuit of that module.

The digital pulse-width modulation signal of each module can be obtained in various ways. For instance, the signal may be obtained using a specific hardware circuit or using software and a microprocessor.

According to a particularly advantageous embodiment of the circuit of the present invention, the means for generating a digital pulse-width modulation signal in each supply module comprises a ramp generator. These ramp generators are synchronized with one another by means of a synchronization signal on the share bus, which in one embodiment is the digital share signal. In this way, a signal connection bus (the share bus) can be use to connect the various modules and a separate bus for carrying a synch signal is not necessary.

The circuit can be connected to the share bus using an electronic switch, an opto-electronic coupler, a diode, or in any other suitable way. In general, the connection is such that the digital share signal is the inverse of the digital pulse-width modulation signal generated by the dominant supply module.

According to one practical embodiment of the invention, the means for generating a digital pulse width modulation signal in each power supply module also includes a comparator. Each comparator includes a first input that is connected to the output of a ramp generator and a second input that is connected to a signal that is proportional to the current delivered by the power supply module associated with that comparator. Each comparator generates a digital pulse width modulation signal, which is a function of the current delivered by the power supply module associated with comparator. The outputs of the comparators are applied, directly or indirectly, to the share bus in such a way that there is present on the share bus a signal that is a function of the output of the comparator of the dominant module.

In each power supply module, the digital share signal and the digital pulse-width modulation signal generated by the respective comparators are used to generate an error signal that is proportional to the difference between the current delivered by the supply module to which the comparator belongs and the current delivered by the dominant supply module. This error signal is then used in the driving circuit of the power supply module associated with the error signal to increase the current delivered by that module.

Further advantageous characteristics and embodiments of the circuit according to the invention are specified in the attached dependent claims.

According to the invention, a method is also provided for controlling the current delivered by a plurality of supply modules that are connected to a common load. This method is designed to be used with power supply modules equipped with a driving circuit for controlling the current delivered by the module connected together using a share bus. The method includes the steps of applying a signal that is proportional to the current delivered by a dominant supply module to the share bus, the dominant supply module being the supply module that instantaneously delivers the highest current, and using that signal in each power supply module to correct the current delivered by each power supply module.

The method includes the steps of generating, for each power supply module, a digital pulse-width modulation signal (PWM signal) that is a function of the current delivered by the power supply module associated with the digital pulse width modulation signal, applying, on the share bus, a digital pulse-width modulation share signal determined by the current delivered by the dominant supply module, comparing the digital share signal with the pulse-width modulation signal generated by each supply module, and generating, for each power supply module, an error signal that is a function of the digital pulse-width modulation signal associated with a respective module and of the digital share signal, and hence a function of the difference between the current delivered by the supply module in question and the current delivered by the dominant supply module. The error signal constitutes a feedback signal for the driving circuit of the power supply module associated with the error signal.

Further advantageous characteristics and embodiments of the method according to the invention are specified in the dependent claims.

### BRIEF DESCRIPTION OF THE DRAWINGS

The invention will be better understood from the ensuing description and that attached drawings, which shows a practical non-limiting embodiment of the invention.

FIG. 1 shows a diagram of a current-sharing supply system having a load and a series of supply modules.

FIG. 2 shows a circuit diagram of an individual power supply module.

FIG. 3 shows a circuit diagram of the ramp generator of the circuit of FIG. 2.

FIGS. 4(a) and 4(f) illustrate the waveforms of the signals for control of current sharing.

FIGS. 5 and 6 show circuit diagrams of two alternative embodiments of the power supply module shown in FIG. 2.

FIG. 7 shows an embodiment similar to the embodiment of FIG. 2 except for the non-inverting logic.

FIGS. 8(a) to 8(e) show the wave forms of the signals for the control of current sharing in the example of the embodiment illustrated in FIG. 7.

FIG. 9 shows a diagram of an embodiment of the ramp-generator circuit for the circuit solution illustrated in FIG. 8.

FIG. 10 shows a further embodiment that employs a microprocessor.

### DESCRIPTION OF THE PREFERRED EMBODIMENT

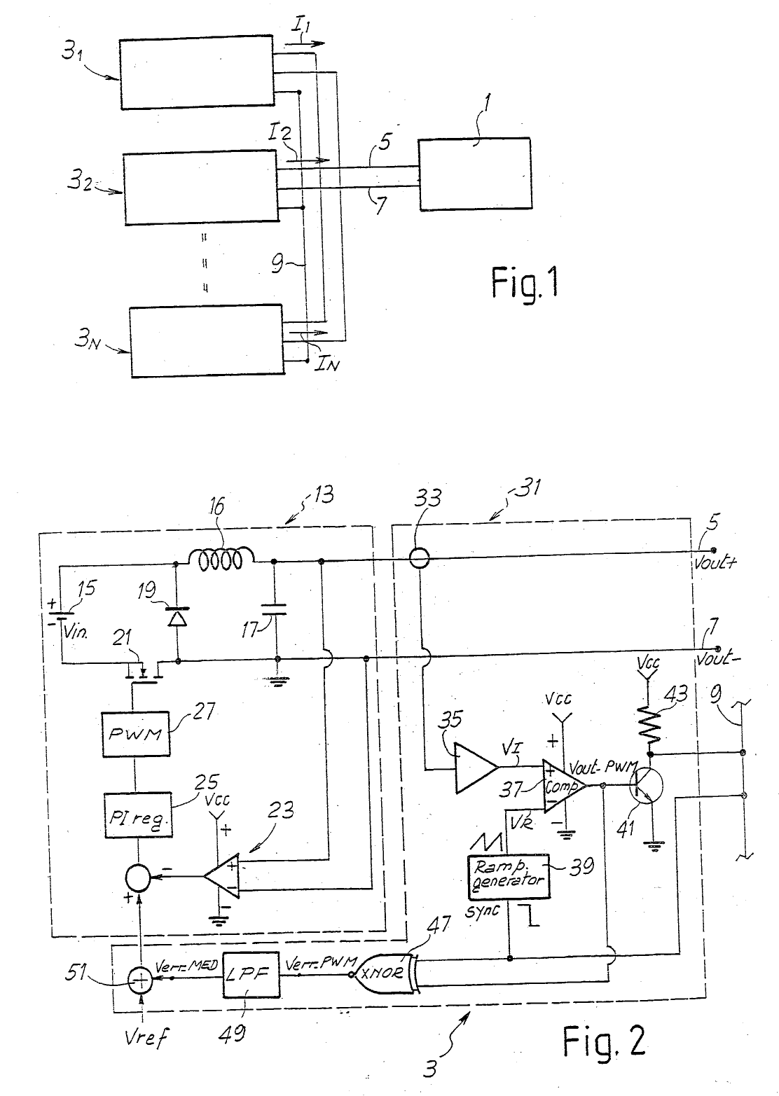

FIG. 1 is a schematic representation of a current-sharing supply system. The reference number 1 designates a load that is supplied in parallel by a series of supply modules or power supplies, designated by 3₁, 3₂, 3_{N}. Each power supply 3₁, 3₂, . . . 3_{N} has two poles (a positive pole and a negative pole) for connection to the supply line 5, 7 of the load 1, so that the individual modules supply the load 1 in parallel. In additional to the connection with the supply line 5, 7, each supply module is connected to a share bus 9, which may consist of a single wire.

Each supply module supplies a current 1₁, 1₂, . . . 1_{N} to the load. The sum of the currents delivered by the individual modules is equal to the total current 1 absorbed by the load 1. The share bus 9 includes a signal that is a function of the current delivered by the dominant supply module, i.e., by the supply module that is instantaneously delivering the largest current. This signal, which in the present context is referred to as a “digital share signal”, is generated in the way described in detail below. On the basis of this signal, each supply module (with the exception of the dominant supply module) will modify its own operating conditions to increase the current delivered, tending to balance the system, i.e., to bring it into conditions such that the various supply modules basically all deliver the same current. It is clear that by increasing the current delivered by the supply modules other than the dominant module there will be a consequent reduction in the current delivered by the dominant supply module.

The various supply modules 3 are identical to one another and FIG. 2 is a schematic illustration of a possible embodiment of one of these power supply modules. The reference number 13 designates, as a whole, the DC/DC converter of the supply module. The converter 13 is connected to a dc voltage source 15 and to the lines 5, 7 for connection to the load. Vout+ and Vout− indicate the voltages on the two poles for connection to the load. The converter is schematically represented as a device comprising an inductor 16, a leveling capacitor 17, a diode 19, and an electronic switch 21. The opening and closing of the switch 21 enables adjustment of the output voltage of the converter. The converter further comprises a feedback branch, 23, for controlling the output voltage. The feedback branch reads the output voltage from the DC/DC converter 13 and issues a feedback signal, which is added to a reference voltage V_{ref} of a regulation block 25 (for example, a proportional-integral, or PI, regulator), connected to a PWM circuit 27, which, in turn, drives the switching of the electronic switch 21. Irrespective of the error signal, which is generated in the way described hereinafter according to the signal present on the share bus, the feedback branch 23 controls the DC/DC converter in such a way as to maintain the output voltage constant by means of the driving circuit that comprises the voltage regulator 25 and the PWM circuit 27.

The configuration of the DC/DC converter 13 and of the driving circuit with the corresponding feedback branch 23 is purely exemplary and the invention may be applied to different configurations of the converter, as will be evident to persons skilled in the art.

The reference number 31 designates, as a whole, the control circuit for controlling the current delivered by the supply module 3. This circuit comprises a current sensor (for example, a resistor), designated as a whole by 33, which reads the current delivered by the supply module to the lines 5, 7 for connection to the load 1. From this reading, via an operational amplifier 35, an analog voltage signal V₁ is generated. The voltage V₁ is proportional to the current delivered by the supply module 3. This analog voltage signal (which in traditional systems would be applied via a diode directly to the share bus 9) is applied to an input of a comparator 37. A ramp signal, V_{R}, generated by a ramp generator 39 is applied to the second input of the comparator 37.

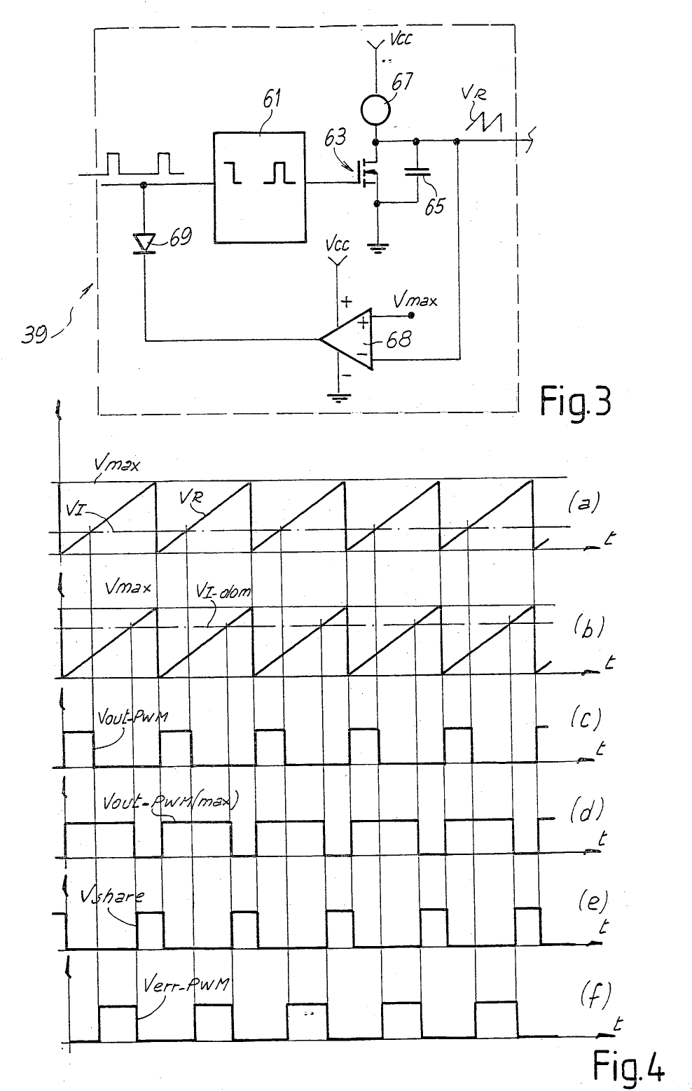

The ramp signals applied to each comparator of the individual supply modules are synchronized together via the circuit illustrated in FIG. 3 and described below.

The output of the comparator 37, designated by Vₒᵤₜ_{_{—}}_{PWM} is a digital pulse-width modulation signal (PWM signal). The duration of the signal is proportional to the current delivered by the supply module. This digital pulse-width modulation signal is applied to the base of the transistor 41. The emitter of the transistor 41 is connected to ground and the collector is connected to a dc voltage Vcc through a resistor 43 and to the share bus 9. When the signal on the base of the transistor 41 is low, the transistor is inhibited, and hence the collector is at the voltage Vcc. When the signal on the base of the transistor 41 is high, the transistor is conducting, and the collector voltage is zero. In other words, on the collector of the transistor 41 there is a signal that is the inverse of the digital PWM signal Vₒᵤₜ_{_{—}}_{PWM} output from the comparator 37.

Since all the supply modules are connected to the share bus 9 in the same way, i.e., by means of a transistor 41 driven by the output signal of the corresponding comparator 37, the signal on the share bus 9 will be a low signal whenever at least one of the transistors 41 is conducting, i.e., whenever the voltage V₁ for at least one of the power supply modules is higher than the voltage of the corresponding ramp signal V_{R}. Consequently, the digital share signal Vₛₕₐᵣₑ on the share bus 9 will always be low, except when the voltage signal V₁ corresponding to the dominant supply module is higher than the ramp signal V_{R}.

The control circuit 31 further comprises an exclusive NOR logic gate (XNOR gate), designated by 47, that includes inputs that are connected to the share bus 9 and to the output of the comparator 37. Consequently, a digital pulse-width modulation signal, i.e., the PWM signal (Vₒᵤₜ_{_{—}}_{PWM}) of the supply module to which the gate itself belongs, as well as the digital share signal Vₛₕₐᵣₑ, will be applied to the logic gate 47.

The output of the logic gate 47 is filtered by a low-pass filter 49, and the output of the filter 49, which constitutes the error signal, is added to a reference voltage V_{ref} in an adder 51. The resulting signal is a feedback signal that is sent to the regulator 25.

Operation of this circuit is described in what follows with reference to FIGS. 4(a) and 4(f) and to a system that comprises just two supply modules. It is noted, however, that this circuit could be used with a system having any number, n, of power supply modules.

When each of the supply modules delivers current to the load 1, the analog signal V₁, which is proportional to the current delivered, is generated using the amplifier 35. The signal V₁ is compared with the ramp signal V_{R} in the comparator 37. FIGS. 4(a) to 4(c) illustrate, respectively, the waveforms of the input signals to the comparator 37 of one of the two supply modules considered and of the corresponding output signal. The PWM signal at output from the comparator, designated by Vₒᵤₜ_{_{—}}_{PWM} is high as long as V₁ is higher than the voltage of the ramp signal V_{R}. When V₁<V_{R}, the output signal of the comparator goes low.

FIGS. 4(b) and 4(d) present the waveforms of the same signals for the second supply module. In the example illustrated, the current delivered by the second supply module is greater than the current delivered by the first supply module. Consequently, the second supply module is the dominant supply module of the system. The input signal to the comparator is designated, in this case, by V_{I}_{_{—}}ₘₐₓ to mean that this is (between the two output signals from the two amplifiers 35) the greater analog signal. The digital pulse-width modulation signal at output from the comparator is designated by Vₒᵤₜ_{_{—}}_{PWM(max)}. This signal is high for a time interval greater than the signal Vₒᵤₜ_{_{—}}_{PWM} in so far as the voltage at output from the corresponding amplifier 35 is higher than that of the first supply module.

The two signals V_{ou.}_{_{—}}_{PWM} and Vₒᵤₜ_{_{—}}_{PWM(max)} are used for driving the two transistors 41, and consequently, there will be a digital share signal, designated by Vₛₕₐᵣₑ, the waveform of which is represented in FIG. 4(e), on the share bus 9. The signal Vₛₕₐᵣₑ is the inverse of the signal Vₒᵤₜ_{_{—}}_{PWM(max)} in so far as the share bus will be isolated form ground (zero potential) only when both of the transistors 41 are open and hence only in the time interval of inhibition of the transistor 41 belonging to the dominant supply module.

In each supply module the digital share signal Vₛₕₐᵣₑ and the digital pulse-width modulation signal of the same module (Vₒᵤₜ_{_{—}}_{PWM}) are applied to the inputs of the XNOR gate 47. This gate is characterized by the property that the output is in the low state (logic value 0) when either only the first input or only the second input is in the high state (logic value 1), and is in the high state (1) when both of the inputs are at the same time in the low state (0) or at the same time in the high state (1). This is therefore defined by the following truth table:

| A | B | Y |
|---|---|---|
| 0 | 0 | 1 |
| 0 | 1 | 0 |
| 1 | 0 | 0 |
| 1 | 1 | 1 |

Consequently, the output of the logic gate will always be zero in the dominant supply module since the two signals applied to the inputs of the logic gate 47 are each the inverse of the other, In the other supply module, which delivers a lower current, there will be a pulse-width modulation error signal (PWM signal), designated by Vₑᵣᵣ_{_{—}}_{PWM}, the waveform of which is represented in FIG. 4(f), at output from the logic gate 47. In each time interval of duration of a ramp, the signal is high for the whole time during which the current delivered by the supply module in question is lower than the current delivered by the dominant supply module. By averaging the signal Vₑᵣᵣ_{_{—}}_{PWM} by means of the low-pass filter 49, an average error signal Vₑᵣᵣ_{_{—}}_{MED} is obtained which is substantially constant and the level of which is proportional to the duration of the signal Vₑᵣᵣ_{_{—}}_{MED}, and hence to the difference between the currently delivered by the dominant supply module and the current delivered by the supply module to which the error signal refers. The lower the current delivered by the non-dominant supply module compared to the current delivered by the dominant module, the longer the time during which the signal Vₑᵣᵣ_{_{—}}_{PWM} is high, and hence the greater the signal Vₑᵣᵣ_{_{—}}_{MED}. This signal is fed back and used to drive the non-dominant supply module and tends to increase the voltage, and consequently the current, output by the non-dominant supply module.

What has been described above for a two-supply-module system obviously may be extended to a system with n supply modules, where in each module an error signal Vₑᵣᵣ_{_{—}}_{MED} will be generated with the same modalities described above.

In order to obtain synchronization of all the ramp signals V_{R} of the various supply modules, it is in principle possible to use a synchronization bus which connects the modules to a single ramp generator. However, this increases the complexity of the circuit and the wiring. It is therefore advisable to synchronize the ramp generators 39 of the various supply modules using the digital share signal present on the share bus 9. For this purposes, the circuit illustrated in FIG. 3 may be used.

The circuit comprises a monostable multivibrator 61, to the input of which is applied the digital share signal arriving from the share bus 9. The output of the monostable multivibrator 61 is connected to the base of a transistor 63 which functions as a switch set in parallel with a capacitor 65. The capacitor 65 is connected by one plate to a current supply 67 and connected by the other plate to ground. When the transistor 63 is conducting, the capacitor 65 discharges. When the transistor 63 is open, the capacitor charges, with a time constant defined by the characteristics of the circuit, using current delivered by the source 67. The voltage between the plates of the capacitor 65 constitutes the ramp signal V_{R}.

The trigger signal of the monostable multivibrator 61 is represented by the trailing edge of the digital share signal on the share bus 9. Consequently, whenever a digital share signal Vₛₕₐᵣₑ switches from the high state to the low state, the monostable multivibrator issues a signal that sends the transistor 63 into conduction. The duration of the output signal of the monostable multivibrator 61 is sufficient for discharging the capacitor 65 completely. When the output of the monostable multivibrator 61 returns to zero, the capacitor 65 starts charging. From a comparison of FIGS. 4(a), 4(b), and 4(e), it may be noted that in effect the ramp starts at each trailing edge of the signal Vₛₕₐᵣₑ. The time required for discharging of the capacitor is not shown in this representation.

The ramp-generator circuit 39 further comprises a connection branch between the output of the ramp signal and the input of the monostable multivibrator 61. This branch includes, in series, a comparator 68 and a diode 69. Applied to the negative input of the comparator 68 is the ramp signal V_{R} and applied to the positive input is a pre-set voltage, Vₘₐₓ. The voltage Vₘₐₓ represents the maximum value that the ramp signal V_{R} can reach. Normally, the output of the comparator 68 is high (V_{R}<Vₘₐₓ). If, in the absence of the trailing edge of the digital share signal, the voltage V_{R} reaches the value Vₘₐₓ, the output of the comparator 68 goes low and sends the diode 69 into conduction, with a consequent generation of a trailing edge on the signal at the input to the monostable multivibrator 61.

The possible lack of synchronization between the ramps generated by the various circuits of the individual modules is corrected by the ramp-generator circuit 39 described above. Synchronization is obtained without any need for a dedicated connection between the various modules, but through the same signal on the share bus.

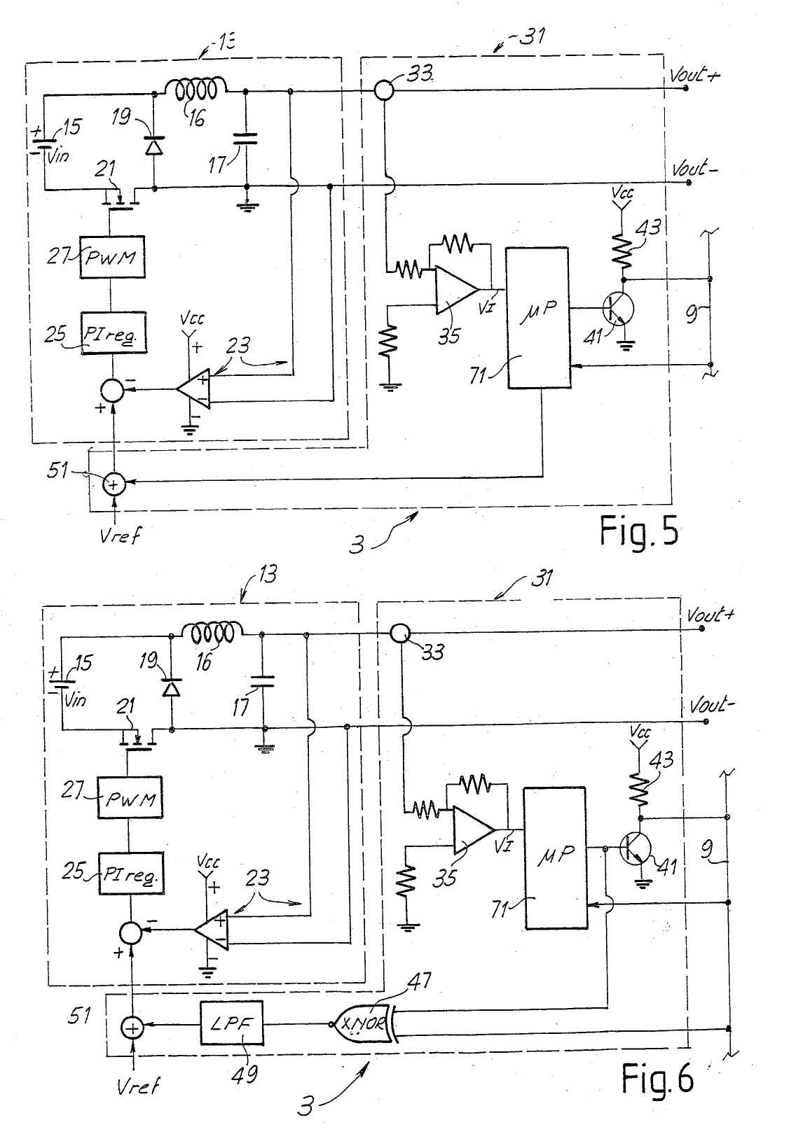

The functions performed by the control circuit 31 described with reference to FIG. 2 and by the ramp-generator circuit 39 descried with reference to FIG. 3 may be entirely or partially performed via software by means of an appropriately programmed microprocessor. FIG. 5 shows an embodiment in which all the functions are performed via software by means of a microprocessor 71. In this case, the signal V₁ and the signal Vₛₕₐᵣₑ are applied to the inputs of the microprocessor 71. The remaining parts of the circuit are designed by reference numbers that are the same as those of the corresponding parts of the circuit in FIG. 2.

FIG. 6 illustrates an intermediate solution in which only some of the functions are performed via software by means of a microprocessor 71. The other components of the circuit are designated by reference numbers that are the same as those adopted for components that are the same as or equivalent to the components of the circuit of FIG. 2.

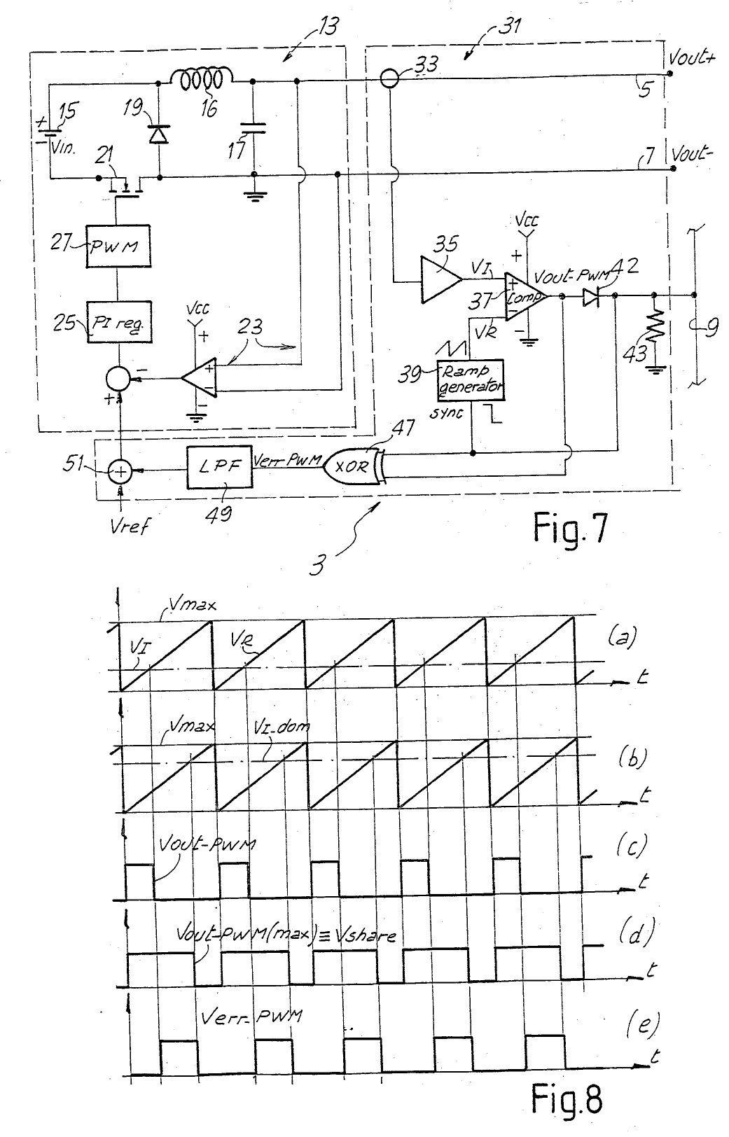

FIG. 7 show as an embodiment that is modified with respect the diagram of FIG. 2. Parts that are the same or that correspond are designated with the same reference numbers. In this example of embodiment, each supply module is connected to the share bus 9 by means of a diode 41 rather than by a transistor 41. The signal on the share bus is therefore represented by the output signal of the comparator 37 of the dominant supply module, which is not inverted, in contrast with the solution of FIG. 2. FIG. 8(a) shows the waveform of the ramp signal V_{R} and the output voltage V₁ of the amplifier 35, which is proportional to the current delivered by the non-dominant supply module. FIG. 8(b) shows the same waveforms for the dominant supply module, where V_{I-dom} is the output signal of the amplifier 35 of the dominant supply module. FIGS. 8(c) and 8(d) show the signals Vₒᵤₜ_{_{—}}_{PWM} and Vₒᵤₜ_{_{—}}_{PWM(max)}, which are the output signals from comparator 37 of the non-dominant module and of the dominant module, respectively. Because the various supply modules are connected to the share bus 9 using the diode 42, the digital share signal Vₛₕₐᵣₑ coincides with the signal Vₒᵤₜ_{_{—}}_{PWM(max)}, and consequently the diagram of FIG. 8(d) also represents the digital PWM share signal Vₛₕₐᵣₑ.

For each supply module, the circuit also comprises an exclusive OR logic gate having inputs that are connected to the digital share signal (Vₒᵤₜ_{_{—}}_{PWM(max)}=Vₛₕₐᵣₑ) and the digital PWM signal Vₒᵤₜ_{_{—}}_{PWM} of the module associated with the exclusive OR logic gate. The truth table of this logic gate is given by:

| A | B | Y |
|---|---|---|
| 0 | 0 | 0 |
| 0 | 1 | 1 |
| 1 | 0 | 1 |
| 1 | 1 | 0 |

Its output is represented by the signal of FIG. 8(e), which, in this case, constitutes the error signal Vₑᵣᵣ_{_{—}}_{PWM}. The greater the difference between the signal Vₒᵤₜ_{_{—}}_{PWM} and the share signal Vₛₕₐᵣₑ=Vₒᵤₜ_{_{—}}_{PWM(max)}, the longer the duration of this signal. This signal is sent to a low-pass filter 49, and then to the adder 51 to be used as described with reference to the diagram of FIG. 2.

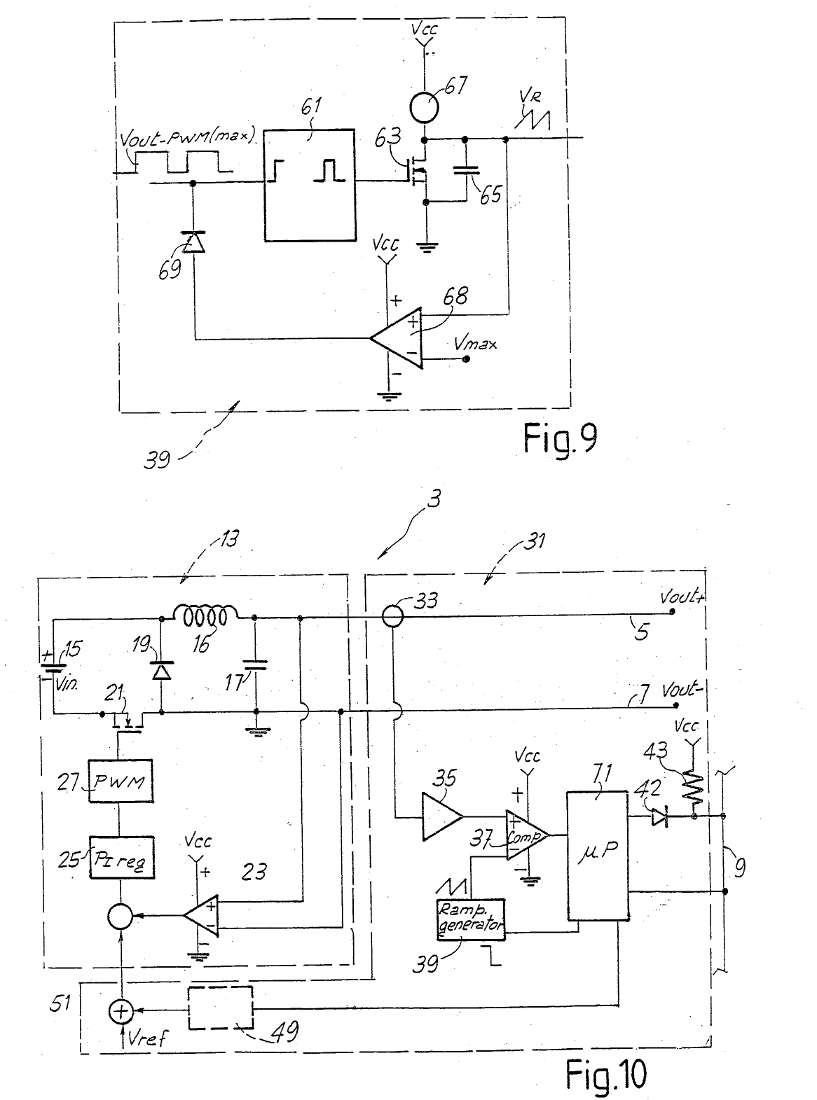

FIG. 9 presents the circuit diagram of the ramp generator shown in FIG. 7. Reference numbers that are the same designate parts that are the same as or correspond to the parts of the circuit illustrated in FIG. 3. The circuit of FIG. 9 is basically the same as the circuit shown in FIG. 3, except for the different connection of the inputs to the comparator 68, which are inverted with respect to the previous case, and the different connection of the output of the comparator 68 to the trigger input of the monostable multivibrator 61. In addition, in this case, the monostable multivibrator 61 is activated by the leading edge, instead of the trailing edge, of the share signal.

FIG. 10 illustrates a different embodiment of the circuit according to the invention, in which reference numbers that are the same designate parts that are the same as or correspond to the parts of the previous embodiment. In this case, as in the examples of FIGS. 5 and 6, some of the functions of the circuit are performed by means of a microprocessor, which is again designated by 71. In particular, the digital pulse-width modulation signal coming from the comparator 37 is applied to the input of the microprocessor 71 and, with regard to the microprocessor of the dominant module, the microprocessor sends the digital share signal onto the share bus 9. Each microprocessor receives, then, at input the digital share signal and synchronizes the ramp generator 39. In addition, each microprocessor generates directly the error signal or a digital pulse-width modulation signal, which is then passed through a low-pass filter 49.

It is understood that the drawings only illustrate a practical embodiment of the invention, which may vary in its embodiments and arrangements without thereby departing from the scope of the underlying idea.

Thus, although there have been described particular embodiments of the present invention of a new and useful Current-Sharing Modular Power Supply Method and Circuit, it is not intended that such references be construed as limitations upon the scope of this invention except as set forth in the following claims.

1. A control circuit for a current-sharing power supply module, comprising:
a digital signal generating circuit adapted to be connected to an output of the power supply module;
a share signal generating circuit connected to the digital signal circuit and adapted to be connected to a share bus; and
an error signal generating circuit connected to the digital signal circuit and adapted to be connected to the share bus and an input of the power supply module.

2. The control circuit of claim 1, wherein the digital signal generating circuit includes:
a current sensor adapted to be connected to the output of the power supply module;
an operational amplifier circuit connected to the current sensor;
a comparator circuit having one input connected to an output of the operational amplifier; and
a ramp generator circuit connected to a second input of the comparator circuit and having an input adapted to be connected to the share bus.

3. The control circuit of claim 2, wherein the share signal generating circuit includes an electronic switch adapted to be connected to the share bus.

4. The control circuit of claim 3, wherein the error signal generating circuit includes:
an exclusive NOR logic gate having one input connected to an output of the comparator circuit and a second input adapted to be connected to the share bus; and
a low pass filter connected to an output of the exclusive NOR logic gate.

5. The control circuit of claim 4, wherein the ramp generator circuit includes:
a monostable multivibrator having an input adapted to be connected to the share bus;
an electronic switch connected to an output of the monostable multivibrator;
a capacitor connected in parallel with the electronic switch;
a current supply circuit connected to the electronic switch and the capacitor;
a second comparator circuit having one input connected to a reference voltage and a second input connected to an output of the ramp generator; and
a diode connected between an output of the second comparator circuit and the input of the monostable multivibrator.

6. The control circuit of claim 5, wherein the digital signal generating circuit, the error signal generating circuit, or both are implemented using a microprocessor.

7. The control circuit of claim 2, wherein:
the share signal generating circuit includes a diode adapted to be connected to the share bus; and
the error signal generating circuit includes:
an exclusive OR logic gate having one input connected to an output of the comparator circuit and a second input adapted to be connected to the share bus; and
a low pass filter connected to an output of the exclusive OR logic gate.

8. The control circuit of claim 7, wherein the ramp generator circuit includes:
a monostable multivibrator having an input adapted to be connected to the share bus;
an electronic switch connected to an output of the monostable multivibrator;
a capacitor connected in parallel with the electronic switch;
a current supply circuit connected to the electronic switch and the capacitor;
a second comparator circuit having one input connected to a reference voltage and a second input connected to an output of the ramp generator; and
a diode connected between an output of the second comparator circuit and the input of the monostable multivibrator.

9. The control circuit of claim 8, wherein the digital signal generating circuit, the share signal generating signal circuit, the error signal generating circuit, or any combination thereof are implemented using a microprocessor.

10. A control circuit for balancing load currents delivered by a plurality of power supply modules, each power supply module including a driving circuit for controlling the current delivered by the power supply module associated with the driving circuit, the power supply modules being connected together using a share bus, comprising:
means, in each power supply module, for generating a digital pulse width modulation signal having a pulse duration that is proportional to the current delivered by the power supply module;
means for connecting each power supply module to the share bus so that a digital share signal is generated on the share bus that is a function of the digital pulse width modulation signal generated by a power supply supplying more current than the other power supply modules;
means, in each power supply module, for generating an error signal based on the pulse width modulation signal of the power supply module and the share signal; and
wherein the error signal in each power supply module constitutes a feedback signal for the driving circuit of the power supply module.

11. The circuit according to claim 10, wherein the digital pulse-width modulation signals of the supply modules are synchronized with one another.

12. The circuit according to claim 11, wherein the means for generating a digital pulse-width modulation signal in each power supply module comprises a ramp generator and the ramp generators are synchronized with one another.

13. The circuit according to claim 12, wherein the digital pulse-width modulation signals of the power supply modules are synchronized together by means of the digital share signal.

14. The circuit of claim 13, wherein:
associated with each supply module is a ramp generator, the output of which is applied to an input of a respective comparator, there being applied to the second input of the comparator an analog signal that is proportional to the current delivered by the supply module;
each comparator associated with each supply module generates said digital pulse-width modulation signal, which is a function of the current delivered by the respective supplied module; and
the outputs of the comparators are connected, directly or indirectly, to said share bus in such a way that there is present, on the share bus, a signal that is a function of the output of the comparator of the dominant module.

15. The circuit of claim 14, wherein each ramp generator comprises a monostable multivibrator activated by an edge of the digital share signal.

16. The circuit of claim 15, wherein the ramp generator comprises a circuit containing a capacitive element, and in that the output pulse of the monostable multivibrator is applied to said circuit containing the capacitive element, which is charged by a current source, said pulse causing discharging of the capacitive element, the difference in voltage between the plates of said capacitive element constituting said ramp.

17. The circuit of claim 7, wherein the difference in voltage between the plates of the capacitive element is applied to a first input of a comparator, on the second input of which there is present a maximum reference voltage, the output of the comparator being connected to the input of the monostable multivibrator for generating trigger signal at input to said monostable multivibrator if the voltage difference between the plates of the capacitive element reaches the maximum reference voltage before said edge of the share signal that causes activation of the monostable multivibrator arrives on said share bus.

18. The circuit of claim 17, wherein each supply module comprises a microprocessor.

19. The circuit of claim 18, wherein the microprocessor generates said error signal according to the share signal and to the digital pulse-width modulation signal of the supply module to which it belongs.

20. The circuit claim 19, wherein the microprocessor generates said digital pulse-width modulation signal of the supply module to which it belongs.

21. The circuit of claim 22, wherein each supply module comprises a logic gate to the inputs of which the digital pulse-width modulation signal generated by said supply module an the digital share signal are applied, and in that the oup0t of said logic gate is applied to a low-pass filter for generating said error signal.

22. The circuit of claim 21, wherein each of said supply modules is connected to the share bus by means of a transistor.

23. The circuit according to claim 22, wherein the digital pulse-width modulation signals of the supply modules are synchronized with one another by means of the trailing edge of the digital share signal.

24. The circuit of claim 23, wherein each of said supply modules is connected to the share bus via a diode.

25. The circuit of claim 24, wherein the digital pulse-width modulation signals of the supply modules are synchronized with one another by means of the lead edges of the digital share signal.

26. A method for controlling the current delivered by a plurality of supply modules which are connected to a common load and each of which is connected to a driving circuit for controlling the current delivered by said module, in which on a share bus that joins said supply modules a signal is applied that is proportional tot he current delivered by a dominant supply modules, said signal on the share bus being sued by each supply module for correcting the current that its delivers; characterized by:
generating, for each supply module, a digital pulse-width modulation signal (PWM signal) that is a function of the current delivered by the respective supply module;
applying, on the share bus, a digital pulse-width modulation share signal which is a function of the digital pulse-width modulation signal of the dominant supply module;
for each supply module, comparing the digital share signal with the digital pulse-width modulation signal generated by said supply module; and
for each supply module, generating an error signal that is a function of the digital share signal and of the digital pulse-width modulation signal generated by said supply module, said error signal constituting a feedback signal for the driving circuit of the respective supply module.

27. The method of according to claim 26, characterized in that the digital pulse-width modulation signals of the various supply modules are synchronized with one another.

28. The method according to claim 27, characterized by synchronizing with one another the digital pulse-width modulation signals of the various supply modules by means of the share signal.

29. The method according to claim 28, characterized in that:
for each supply module an analog signal is generated that is proportional to the current delivered by said supply module; and
the analog signal proportional to the current delivered by each supply module is compared with a ramp, for generating said digital pulse-width modulation signal.

30. The method according to claim 29, characterized in that the ramps of each supply module are synchronized together by means of the digital share signal.

31. The method according to claim 30, characterized in that, for each supply module, the respective digital pulse-width modulation signal and the digital share signal are applied to the input of a logic gate, and in that the output signal of said logic gate is filtered by a low-pass filter for generating said error signal.
